(19) United States
(12) Patent Application Publication
(10) Pub. No.: US 2014/0165906 A1
(43) Pub. Date: Jun. 19, 2014

(54) MAGNETIC MASKS FOR AN ION IMPLANT APPARATUS

(71) Applicant: Varian Semiconductor Equipment Associates, Inc., Gloucester, MA (US)

(72) Inventors: Christopher N. Grant, Dripping Springs, TX (US); Robert B. Vopat, Austin, TX (US)

(73) Assignee: Varian Semiconductor Equipment Associates, Inc., Gloucester, MA (US)

(21) Appl. No.: 14/103,296

(22) Filed: Dec. 11, 2013

Related U.S. Application Data
(60) Provisional application No. 61/736,624, filed on Dec. 13, 2012.

(51) Int. Cl. C23C 14/48

(52) U.S. Cl. CPC C23C 14/48
USPC 118/500; 118/504; 414/800

(57) ABSTRACT

An ion implant apparatus configured to measure the temperature or monitor the degradation of components in the apparatus is provided. The ion implant apparatus may include a platen configured to move in a first direction, a mask frame to hold one or more masks disposed on the platen, a first optical sensor configured to project an optical beam to a second optical sensor, and a measurement bar disposed on the mask frame, the measurement bar raised above the surface of the mask frame to interrupt the optical beam when the platen moves in the first direction.

### RELATED APPLICATIONS

This application claims the benefit of U.S. Provisional Application Ser. No. 61/736,624 filed Dec. 13, 2012, entitled “Magnetically Manipulating Masks for Ion Implantation.”

### FIELD

The present embodiments relate to ion implanters and particularly to securing mask frames for use in ion implantation.

### BACKGROUND

Ion implanters are widely used in electronic device fabrication, including semiconductor manufacturing to control device properties. In a typical ion implanter, ions generated from an ion source are directed as an ion beam through a series of beam-line components that may include one or more analyzing magnets and a plurality of electrodes that provide electric fields to tailor the ion beam properties. The analyzing magnets select desired ion species, filter out contaminant species and ions having undesirable energies, and adjust ion beam quality at a target wafer. Suitably shaped electrodes may modify the energy and the shape of an ion beam.

Additionally, masks may be placed over the target wafer to block areas of the target wafer from being exposed to the ion beam. As will be appreciated, mask alignment is critical to correct implantation. More specifically, properly aligning the mask is required to ensure that the ions are implanted at desired locations in the target wafer. In some ion implanters, a mask frame is used to support or hold one or more masks. This mask frame is positioned over the target wafer in the path of the ion beam to selectively block portions of the target wafer from being exposed to the ion beam. Accordingly, placing the mask frame over the target wafer and aligning the masks to the target wafer are used to correctly implant ions in the target wafer. As will be appreciated, the mask frame may be placed one or more times while the target wafer is undergoing processing in an ion implant apparatus. Each time, the masks may need to be aligned to the target wafer. As such, mask frames that can be repeatedly placed and aligned in an efficient and reliable manner are needed. Such mask frames may improve manufacturing throughput and efficiency.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a mask frame to hold one or more masks is provided. The mask frame may include a mask connected to the mask frame and a ferrous slug disposed in the mask frame, the ferrous slug configured to allow the mask frame to be retained by a transfer mechanism using a magnet.

In one embodiment, an apparatus for placing a mask frame on a carrier may be provided. The apparatus may include a mask frame, a ferrous slug disposed in the mask frame, and a transfer mechanism including a magnet, the magnet configured to clamp to the ferrous slug to retain the mask frame against the transfer mechanism, the transfer mechanism configured to move the mask frame while the mask is retained against the transfer mechanism.

In one embodiment, a method of placing a mask frame on a carrier is provided. The method may include moving a mask frame including a ferrous slug proximate to a carrier, the mask frame retained by a transfer mechanism, the transfer mechanism including a magnet clamped to the ferrous slug, placing the mask frame on the carrier, deactivating the magnet to release the ferrous slug, and moving the transfer mechanism away from the mask frame.

### BRIEF DESCRIPTION OF THE DRAWINGS

FIGS. 1A-1C depict block diagrams of a system for placing a mask frame in an ion implantation apparatus;

FIGS. 2-3 depict perspective views of a mask frame and transfer mechanism;

FIG. 4-5 depict block diagrams of mask frame and carrier; and

FIG. 6 depicts a flow diagram of a method of placing and aligning a mask frame in an ion implant apparatus, all arranged according to at least one embodiment of the present disclosure.

### DETAILED DESCRIPTION

The present embodiments will now be described more fully hereinafter with reference to the accompanying drawings, in which some embodiments are shown. The subject matter of the present disclosure, however, may be embodied in many different forms and should not be construed as limited to the embodiments set forth herein. Rather, these embodiments are provided so that this disclosure will be thorough and complete, and will fully convey the scope of the subject matter to those skilled in the art. In the drawings, like numbers refer to like elements throughout.

Various embodiments described herein provide apparatuses and methods to place and align masks over a workpiece (e.g., wafer, target substrate, or the like) in an ion implant apparatus. In particular, a mask frame having magnets may be rapidly transferred from a transfer mechanism to a carrier and individual masks in the mask frame aligned to workpieces using an alignment pin mechanism. The disclosed mark transfer and alignment apparatuses may be implemented in an ion implant apparatus. For example, the mask transfer and alignment apparatuses may be implemented to repeatedly place a mask frame on a carrier, where the mask frame includes one or more masks and the carrier supports one or more workpieces. The masks may be aligned to the workpieces while the mask frame is placed on the carrier.

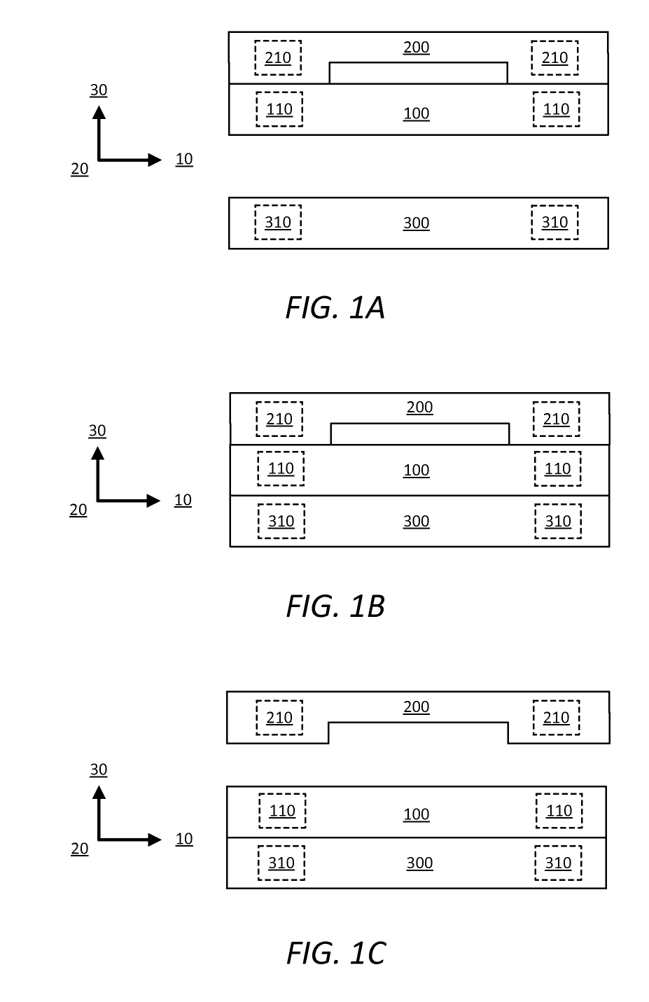

FIGS. 1A-1C illustrate block diagrams of a system 1000 for placing a mask frame 100 in an ion implantation apparatus. In particular, the system 1000 depicts transferring the mask frame 100 between a transfer mechanism 200, and a carrier 300. The mask frame 100, the transfer mechanism 200, and the carrier 300 may be included in an ion implant apparatus. More specifically, the mask frame 100, the transfer mechanism 200, and the carrier 300 may be included in a processes chamber of an ion implant apparatus. In general, FIGS. 1A-1C illustrate transferring the mask frame 100 from the transfer mechanism 200 to the carrier 300. FIG. 1A illustrates the mask frame 100 attached to the transfer mechanism 200, FIG. 1B illustrates the mask frame 100 being transferred from the transfer mechanism 200 to the carrier 300 using magnets (described in greater detail below) and FIG. 1C illustrates the mask frame 100 attached to the carrier 300.

Turning more specifically to FIG. 1A, the mask frame 100 is shown attached to the transfer mechanism 200. The transfer mechanism 200 may be configured to move the mask frame 100 in multiple dimensions in order to place the mask frame 100 on the carrier 300. The transfer mechanism 200 may be operably coupled to an actuator (not shown) to manipulate the transfer mechanism 200 and place the mask frame 100 on the carrier 300. Additionally, as will be detailed below, the mask frame 100 may be retrieved from the carrier 300 by the transfer mechanism 200. With some examples, the actuator may be a robotic arm or other device configured to move the transfer mechanism 200 within a process chamber of an ion implantation apparatus.

The transfer mechanism 200 may move the mask frame 100 to be proximate to the carrier 300. More specifically, the transfer mechanism 200 may move the mask frame 100 in directions 10, 20, and/or 30 to be proximate to the carrier 300. In some examples, the directions 10, 20, and 30 may correspond to the x, y, and z directions, respectively, of an ion implant apparatus. More specifically, an ion implant apparatus may be configured to project an ion beam in the direction 30 towards the carrier 300. The carrier 300 may be configured to support workpieces to be implanted during an ion implant process. The transfer mechanism 200 may place the mask frame 100 on the carrier 300 in order to “mask off” or block portions of the workpieces from being exposed to the ion beam as the ion beam is projected in the direction 30 towards the carrier 300.

As stated, the mask frame 100 may be magnetically transferred between the transfer mechanism 200 and the carrier 300. As such, the transfer mechanism 200 may include magnets 210 to retain the mask frame 100 so the mask frame 100 may be positioned on the carrier 300. It is to be appreciated, that the carrier 300 may include a variety of mechanism to retain the mask frame 100. In some examples (e.g., as described in conjunction with FIGS. 1A-1C) the carrier 300 may also include magnets 310 to retain the mask frame 100 once placed by the transfer mechanism 200. In some examples (not shown) the carrier 300 may include mechanical retaining mechanisms (e.g., hooks, pins, clamps, springs, or the like) to retain the mask frame 100 once placed by the transfer mechanism 200.

In order to be retained by the magnets 210 and/or the magnets 310, the mask frame includes ferrous slugs 110. In some examples, the ferrous slugs 110 may be comprised of steel, a steel alloy, or another material that includes Iron (“Fe”). With some examples, the ferrous slugs 110 may be comprised of 1018 steel. The magnets 210 and 310 may be configured to clamp to the ferrous slugs 110. In some examples, the magnets 210 and 310 may be configured to clamp to the ferrous slugs 110 and minimize a magnetic field (not shown) extending from the ferrous slugs 110.

With some examples, the magnets 210 and 310 may be fabricated of AlNiCo and SmCo or AlNiCo and Nd. In some examples, magnets 210 and 310 AlNiCo and Nd may be used with lower operating temperatures, such as operating temperatures less than approximately 140° C. With some examples, the magnets 210 and/or 310 may be approximately 1 to 4 inches in diameter and height and may be approximately 8 to 12 inches in length. In one particular embodiment, the magnets 210 may be 2 inches by 2 inches by 9.5 inches in dimension and generate over 120 lbs. of clamping force at zero air gap and approximately 35 lbs. of clamping force at an approximate 0.03 inch air gap.

In some examples, magnets 210 may be different shapes, types, and/or strengths than the magnets 310. For example, the magnets 310 are barrel-shaped with a 0.75 inch diameter and 1 inch height, which produce approximately 10 lbs. of clamping force. Furthermore, in some examples, there may be more magnets 310 than magnets 210. In some examples, the total clamping force of the magnets 210 may be greater than or equal to the total clamping force of the magnets 310.

In some examples, the magnets 210 and/or 310 may be switchable (e.g., electronically controlled) to turn on and off in order to transfer the mask frame 100 between the transfer mechanism 200 and the carrier 300. For example, FIG. 1A shows the magnets 210 on and clamping the ferrous slugs 110 so that the mask frame 100 is attached to the transfer mechanism 200. The transfer mechanism 200 may move the mask frame 100 to be adjacent to the carrier 300.

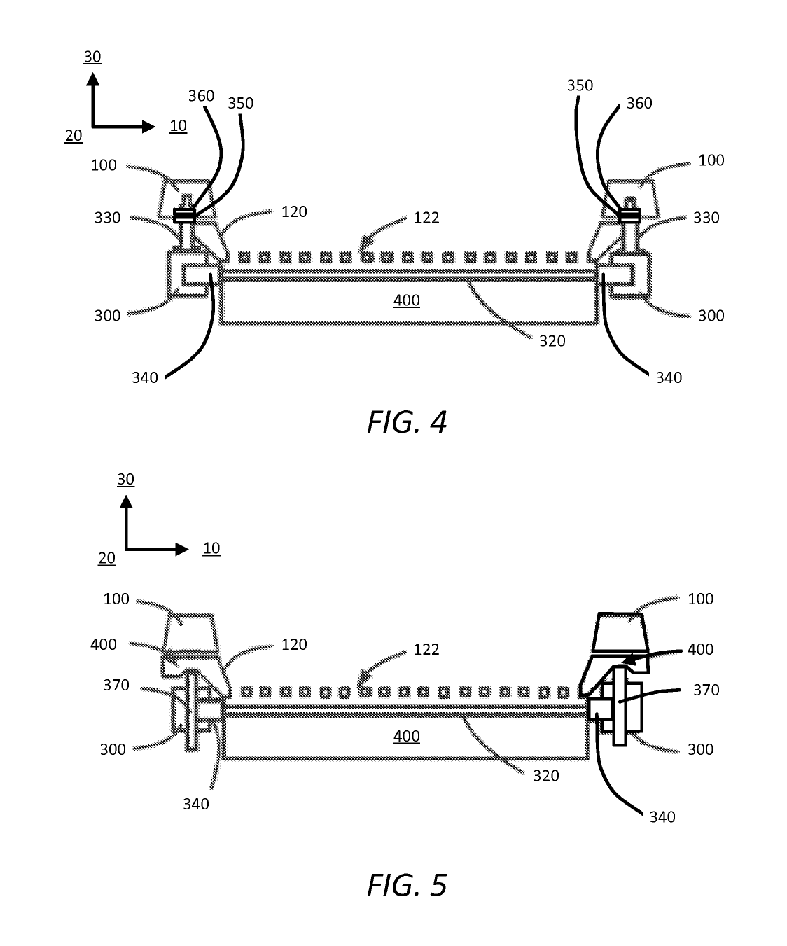

Turning more specifically to FIG. 1B, the mask frame 100 is shown adjacent to the carrier 300. More specifically, the transfer mechanism 200 has moved the mask frame 100 in the direction 30 to be placed on the carrier 300. The mask frame 100 can then be handed off from the transfer mechanism 200 to the carrier 300 by disengaging the magnets 210, thereby releasing the ferrous slugs 110 and the mask frame 100. Additionally, the magnets 310 may be engaged to clamp the ferrous slugs 110. As such, the mask frame 100 may be passed between the transfer mechanism 200 and the carrier 300. In some examples, the magnets 210 may be deactivated (e.g., turned off, powered down, or the like) after the mask frame 100 has partially and/or fully aligned to the carrier 300 (refer to FIGS. 4-5.) In some examples, the magnets 210 may be deactivated after the masks in the mask frame 100 have partially and/or fully aligned to the workpieces supported by the carrier 300 (again, refer to FIGS. 4-5.)

In some examples, the magnets 210 may be configured to change states from on to off in approximately 0.3 seconds. Furthermore, The ferrous slugs 110 may be configured to release any residual charge stored within them from being clamped by the magnets 210, which may aid in the release of the ferrous slugs 110 from the magnets 210. In some examples, the magnets 210 may be permanently activated or deactivated (i.e., on or off). As such, in the event of a power failure, the mask frame 100 may remain held or clamped to the carrier 300 or transfer mechanism 200.

Once the magnets 210 are turned off and the mask frame 100 is transferred to the carrier 300, the transfer mechanism 200 may be moved away from the mask frame 100. Said differently, the transfer mechanism 200 may be moved out of the path of an ion beam so that any workpieces supported by the carrier may be processed in an ion implantation process. For example, the transfer mechanism 200 may be backed away from the mask frame 100 (e.g., in the direction 30) and then moved in the direction 10 and/or 20 so that an ion beam projected in the direction 30 towards the carrier 300 will not strike the transfer mechanism 200. More specifically, during an ion implant process, as an ion beam is projected in the direction 30, the ion beam may be scanned across the mask frame and carrier (e.g., in the direction 10) while the carrier is translated (e.g., in the direction 20 by a platen and drive assembly, or the like) to expose portions of the workpiece to the ion beam.

Turning more specifically to FIG. 1C, the mask frame 100 is shown attached to the carrier 300. The transfer mechanism 200 is shown backed away from the mask frame 100. As described, the mask frame 100 may be transferred between the transfer mechanism 200 and the carrier 300. In some examples, the mask frame 100 may also be retrieved from the carrier 300, by for example, reversing the process described in conjunction with FIGS. 1A-1C. More specifically, the transfer mechanism 200 may be moved adjacent to the mask frame 100, the carrier 300 may release the mask frame 100 (e.g., by deactivating magnets 310, the transfer mechanism 200 may attach to the mask frame 100 (e.g., by activating magnets 210 to clamp to ferrous slugs 110) and the mask frame 100 may be removed from the carrier 300.

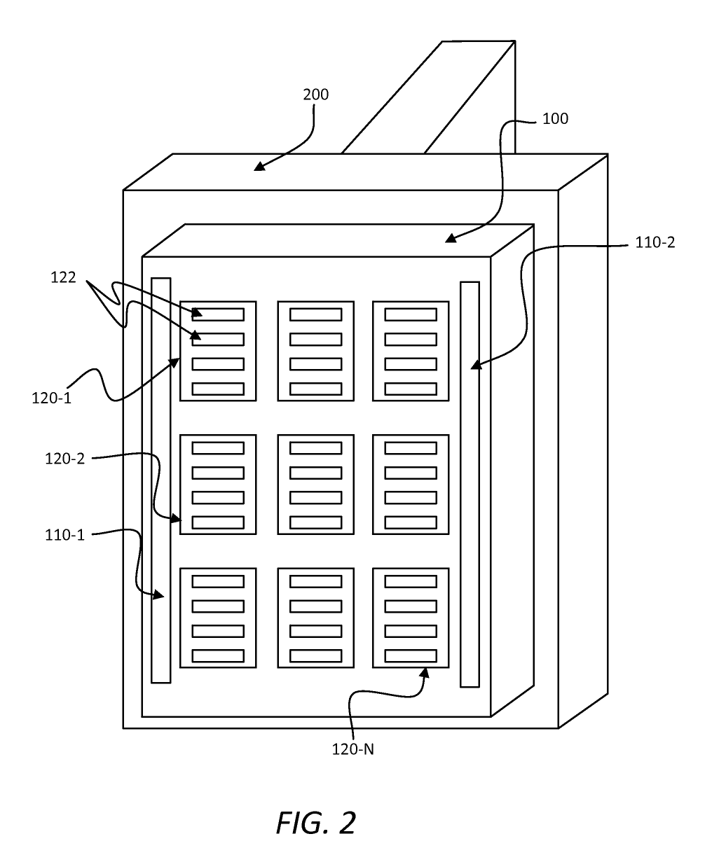

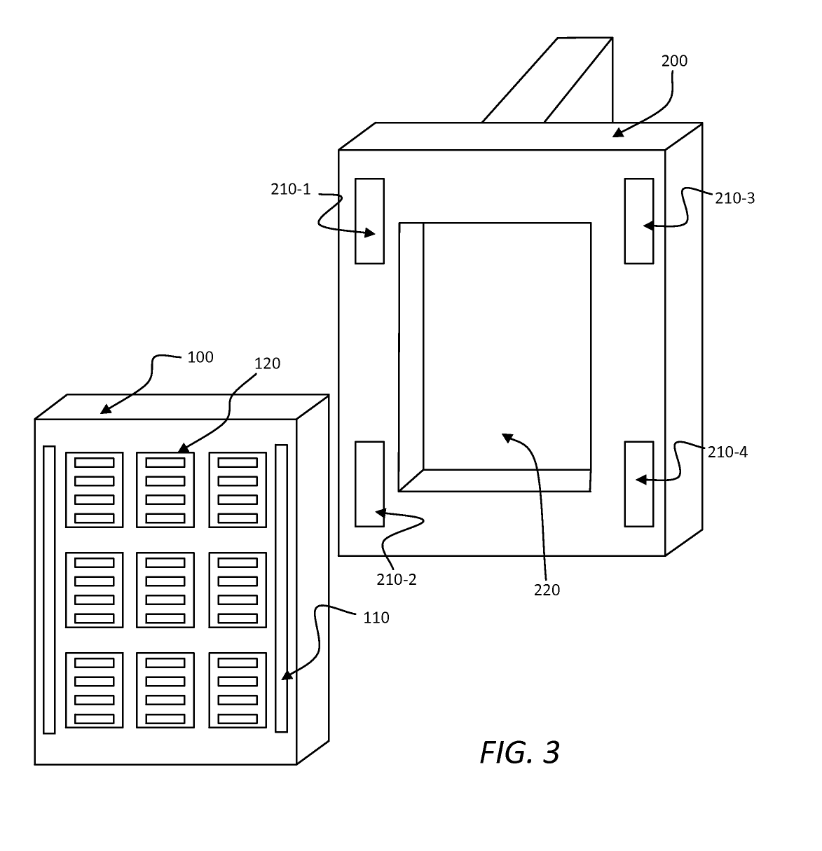

FIGS. 2-3 illustrate perspective views of the transfer mechanism 200 and the mask frame 100. In general, FIG. 2 depicts the mask frame 100 attached to the transfer mechanism 200 while FIG. 3 depicts the mask frame 100 apart from the transfer mechanism 200. Turning more specifically to FIG. 2, the mask frame 100 is depicted having multiple masks 120-1 to 120-N positioned on the mask frame 100. As used herein, a single but unspecific mask may be referred to as mask 120. Furthermore, the masks 120-1 to 120-N collectively may be referred to as masks 120. Additionally, it is to be appreciated, that the number of masks 120 are shown at a quantity to facilitate understanding and is not intended to be limiting. As such, with various examples, more or less masks 120 than depicted may be provided.

In some examples, the masks 120 are disposed on the mask frame 100. With some examples, the masks 120 are disposed in the mask frame 100. Furthermore, each of the masks 120 includes at least one aperture 122. For example, ones of the apertures 122 of the mask 110-1 are denoted with reference designators in FIG. 2. It is to be appreciated that not all apertures 122 are denoted with referenced designators in FIG. 2 for clarity of presentation. Additionally, it is to be appreciated, that the number of apertures 122 are shown at a quantity to facilitate understanding and is not intended to be limiting. Furthermore, it is to be appreciated that the shape of the apertures 122 may vary from implementation to implementations. For example, the apertures 122 may have different shapes, different sizes, different positioning, or the like. Additionally, with some examples, the apertures 122 of one mask 120 may be different than the apertures 122 of another mask 120. Furthermore, it is important to note that the mask frame 100, the masks 120, the apertures 122, and the transfer mechanism 200 are not drawn to scale.

As described above with respect to FIGS. 1A-1C, the mask frame 100 may be transferred between the transfer mechanism 200 and the carrier 300 magnetically. More specifically, the magnets 210 and 310 may be used to clamp the ferrous slugs 110. FIG. 2 depicts the mask frame 100 including a first ferrous slug 110-1 and a second ferrous slug 110-2. As depicted, the first ferrous slug 110-1 and the second ferrous slug 110-2 are disposed on opposite sides of the mask frame 100. In some examples, however, the first ferrous slug 110-1 and the second ferrous slug 110-2 may be disposed on a top and bottom of the mask frame 100. In some examples, more than two ferrous slugs 110 may be provided. It is important to note, however, the positioning of the ferrous slugs 110 may be chosen to provide a secure attachment of the mask frame 100 to the transfer mechanism 200 and to the carrier 300.

With some examples, the first ferrous slug 110-1 and the second ferrous slug 110-2 may be positioned within the mask frame 100. More specifically, the mask frame 100 may be two-part (not shown for clarity) and cavities may be included in the mask frame 100 so the first ferrous slug 110-1 and the second ferrous slug 110-2 can be fastened in the mask frame 100. Furthermore, the mask frame 100 may include apertures (not shown) to expose portions of the first ferrous slug 110-1 and the second ferrous slug 110-2. Said differently apertures may be provided to expose portions of the ferrous slugs 110 so that the magnets 210 and/or 310 may clamp the ferrous slugs 110. In some examples, the mask frame 100 may include more than two ferrous slugs 110. Furthermore, the ferrous slugs 110 may be formed from multiple parts.

Turning more specifically to FIG. 3, the mask frame is depicted apart from the transfer mechanism 200. As can be seen, the transfer mechanism 200 including magnets 210 is depicted. More specifically, the transfer mechanism 200 is depicted including magnets 210-1 to 210-4. It is to be appreciated, that the number of magnets 210 is shown at a quantity to facilitate understanding. In some examples, more or less than 4 magnets 210 may be provided in the transfer mechanism 200. The transfer mechanism 200 is further shown including a cavity 220. The cavity 220 may be positioned such that when the mask frame 100 is attached to the transfer mechanism 200, the masks 120 may not be touched by the transfer mechanism 200. In some examples, the transfer mechanism 200 may be a hollow frame or may be formed from independent arms having the magnets 210 embedded therein.

FIGS. 4-5 illustrate cross-sectional views of the mask frame 100 and the carrier 300. In general, FIGS. 4-5 depict the mask frame 100 attached to the carrier 300 and further depict alignment mechanisms for aligning a mask 120 to a workpiece 320. As described above, the carrier 300 may be configured to support one or more workpieces 320. The carrier 300 and the workpieces 320 may be disposed on a platen 400 in a process chamber of an ion implant apparatus. It is to be appreciated, that FIGS. 4-5 depict a single mask 120 and a single workpiece 320. However, in some implementations, the mask frame 100 may include a number of masks 120 while the carrier 300 (and/or the platen 400) supports a number of workpieces (e.g., multiple workpieces 320, or the like.) Examples are not limited in this context.

In order to control the areas of the workpiece 320 that are implanted with ions during an ion implantation process, the mask 120 is provided with the apertures 122 to allow selected areas (e.g., those visible or exposed through the apertures 122) to be exposed to an ion beam. As described above, in order to ensure that the aperture 122 expose the desired areas of the workpiece 320, the mask 120 is aligned with the workpiece 320. In various examples, the mask 120 may be aligned with the workpiece 320 as part of transferring the mask frame 100 from the transfer mechanism 200 to the carrier 300. FIGS. 4-5 depict alignment apparatuses that may be used to align the mask 120 to the workpiece 320 while the mask frame 100 is placed on the carrier 300.

Turning more specifically to FIG. 4, a cross sectional view of an alignment apparatus including alignment bolts 330 is illustrated. As depicted, the carrier 300 and/or the platen 400 are supporting the workpiece 320. The carrier 300 includes workpiece pins 340 or other mechanisms that press or push the workpiece 320. In some examples, the workpiece pins 340 may be operably connected to the alignment bolts, to push on or press the workpiece as the alignment bolts 330 are pressed on. Said differently, as the alignment bolts 330 are pressed on (e.g., in the direction 30) the workpiece pins 340 will exert pressure on the workpiece 320 to center the workpiece 320 between the alignment bolts 330. With some examples, the workpiece pins 340 may be operably connected to alignment pins (refer to FIG. 5) that operate to center the workpiece 320 below the mask 120.

Furthermore, the alignment bolts 330 are used to center the mask 120 over the workpiece 320. In some examples, the edges of the mask 120 may be configured to slide against the alignment bolts 330 to center the mask 120 over the workpiece 320. In some examples, the mask 120 may include an alignment hole (not shown) in which the alignment bolts 330 fit. In further examples, the alignment hole may be larger than the alignment bolt 330 to provide a loose-fit around the alignment bolt 330 to enable the mask 120 to move slightly.

In some examples, the alignment bolt 330 may have multiple diameters (e.g., as illustrated in FIG. 4.) In some examples, the alignment bolts 330 may be tapered, cone shaped, or have other shapes that facilitate receiving the mask 120. In some examples, a spring 350 and washer 360 are disposed around the alignment bolt 320. With some examples, the spring 350 and the washer 360 may be disposed around the alignment bolt 320 between the mask 120 and the mask frame 100 (e.g., as depicted in FIG. 4.) In some examples, the spring 350 and the washer 360 may be disposed around the alignment bolt 320 between the mask 120 and the carrier 300.

Accordingly, during operation, as the mask frame 100 is placed on the carrier 300, the mask 120 will be centered between the alignment bolts 330. The weight of the mask frame 100 will rest on the alignment bolts 330, which centered the workpiece 320 between the alignment bolts 330. As such, both the mask 120 and the workpiece 320 may be centered between the alignment bolts 330.

Turning more specifically to FIG. 5, another cross sectional view of the alignment apparatus depicted in FIG. 4 is shown. As can be seen, alignment pins 370 are depicted extending through the carrier 300 and pressing against the pin 340. The alignment pins 370 may be operably connected to the workpiece pins 340 to exert pressure on the workpiece pins 340, which further exert pressure on the workpiece 320. The alignment pins 370 may also extend into cavities 400 of the mask 120. During operation, as the alignment pins 370 are centered in the cavity 400 of the mask 120, the mask 120 may be aligned to the workpiece 320. Furthermore, the alignment pins 370 also enable the workpiece 320 to be aligned in the carrier 300. Said differently, the alignment bolts 330, the alignment pins 370, and the workpiece pins 340 may operate together to center the workpiece 320 over the carrier and the mask 120 over the workpiece 320.

Accordingly, FIGS. 4-5 depicts an alignment apparatus that may be used to align the mask 120 to the workpiece 320 as the mask frame 100 is placed on the carrier 300. In some examples, an array of alignment apparatuses as described in FIGS. 4-5 may be provided to align the mask 120 of the mask frame 100 with the workpieces 320 supported by the carrier 300.

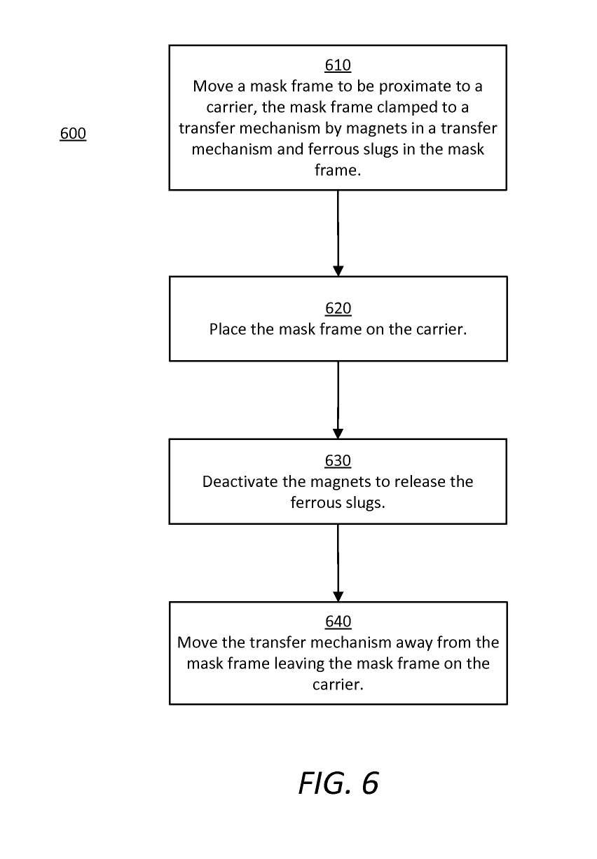

FIG. 6 illustrates a flow chart for a method 600 that may be implemented in an ion implanter to place a mask frame on a carrier and further to align a mask in the mask frame with a workpiece supported by the carrier. For example, the method 600 may be implemented to place the mask frame 100 on the carrier 300 and align the masks 120 with the workpieces 320. Although the method 600 is described with reference to the transport mechanism 200, the mask frame 100, and the carrier 300 of FIGS. 1A-1C, examples are not limited in this context.

The method 600 may begin at block 610. At block 610, move a mask frame to be proximate to a carrier, the mask frame clamped to the carrier by magnets in a transfer mechanism and ferrous slugs in the mask frame, the transfer mechanism 200 may move the mask frame 100 to be proximate to the carrier 300. During such movement, the mask frame 100 may be attached to the transfer mechanism 200 by the magnets 210 and the ferrous slugs 110. More specifically, the magnets 210 may clamp to the ferrous slugs 110 to retain the mask frame 100 against the transfer mechanism 200.

Continuing to block 620, place the mask frame on the carrier, the transfer mechanism 200 may place the mask frame 100 on the carrier 300. Continuing to block 630, disengage the magnets to release the ferrous slugs, the magnets 210 may be deactivated to release the ferrous slugs 110. Continuing to block 640, move the transfer mechanism away from the mask frame 100 leaving the mask frame 100 on the carrier 300, the transfer mechanism 200 may be moved away from the mask frame 100 leaving the mask frame 100 on the carrier 300.

Thus, a mask frame may be aligned to a carrier and individual masks aligned to workpieces using the apparatuses and methods described above. More specifically, the mask frame 100 may be aligned to the carrier 300 and the masks 120 aligned to the workpieces 320. In various examples, the masks 120 may be aligned to within approximately 20 μm of a desired location.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Thus, the claims set forth below should be construed in view of the full breadth and spirit of the present disclosure as described herein.

What is claimed is:

1. An apparatus comprising:
a mask frame;
a mask connected to the mask frame; and
a ferrous slug disposed in the mask frame, the ferrous slug configured to allow the mask frame to be retained by a transfer mechanism using a magnet.

2. The apparatus of claim 1, wherein the mask is moveable in the mask frame to align the mask with a workpiece.

3. The apparatus of claim 1, wherein the ferrous slug is a first ferrous slug, the apparatus further comprising a second ferrous slug disposed in the mask frame.

4. The apparatus of claim 3, wherein the first ferrous slug and the second ferrous slug are disposed on opposite sides of the mask frame.

5. The apparatus of claim 3, wherein the first ferrous slug and the second ferrous slug are comprised of a steel alloy.

6. The apparatus of claim 5, wherein the first ferrous slug and the second ferrous slug are comprised of 1018 steel.

7. An apparatus comprising:
a mask frame;
a ferrous slug disposed in the mask frame; and
a transfer mechanism including a magnet, the magnet configured to clamp to the ferrous slug to retain the mask frame against the transfer mechanism, the transfer mechanism configured to move the mask frame while the mask is retained against the transfer mechanism.

8. The apparatus of claim 7, wherein the magnet is comprised of AlNiCo and SmCo or AlNiCo and Nd.

9. The apparatus of claim 7, wherein the magnet is between 1 and 4 inches in diameter and between 8 and 12 inches in length.

10. The apparatus of claim 7, further comprising a carrier, the transfer mechanism configured to place the mask on the carrier.

11. The apparatus of claim 10, the carrier configured to support a workpiece to be exposed to an ion beam in an ion implant process.

12. The apparatus of claim 11, further comprising a plurality of workpiece pins disposed in the carrier, the workpiece pins configured to press against the workpiece to align the workpiece with a mask in the mask frame when the mask frame is placed on the carrier.

13. The apparatus of claim 12, further comprising a plurality of alignment bolts disposed in the carrier, the alignment bolts configured to align the mask with the workpiece when the mask frame is place on the carrier.

14. The apparatus of claim 7, wherein the magnet is a first magnet, the apparatus further comprising a second magnet disposed in the transfer mechanism, a third magnet disposed in the transfer mechanism, and a fourth magnet disposed in the transfer mechanism.

15. The apparatus of claim 7, wherein the ferrous slug is a first ferrous slug, the apparatus further comprising a second ferrous slug disposed in the mask frame.

16. The apparatus of claim 15, wherein the first ferrous slug and the second ferrous slug are disposed on opposite sides of the mask frame.

17. A method comprising:
moving a mask frame including a ferrous slug proximate to a carrier, the mask frame retained by a transfer mechanism, the transfer mechanism including a magnet clamped to the ferrous slug;
placing the mask frame on the carrier;
deactivating the magnet to release the ferrous slug; and
moving the transfer mechanism away from the mask frame.

18. The method of claim 17, wherein the mask frame includes a mask, the method further comprising placing the mask frame over one or more alignment bolts disposed in the carrier to align the masks frame to a workpiece supported by the carrier.

19. The method of claim 17, further comprising activating a magnet in the carrier to clamp to the ferrous slug.

20. The method of claim 17, further comprising:
deactivating the magnet in the magnet in the carrier to release the ferrous slug;
moving the transfer mechanism proximate to the mask frame;
activating the magnet in the transfer mechanism to clamp to the ferrous slug; and
moving the mask frame away from the carrier.
